(19) United States
(12) Patent Application Publication
(10) Pub. No.: US 2007/0161162 A1
(43) Pub. Date: Jul. 12, 2007

(54) Three-dimensional TFT nanocrystal memory device

(75) Inventor: Pei-Ren Jeng, Hsinchu Hsien (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/524,474

(22) Filed: Sep. 21, 2006

(30) Foreign Application Priority Data
Dec. 23, 2005 (TW) 094146006

(51) Int. Cl. H01L 21/84

(52) U.S. Cl. 438/149; 257/E29.151

(57) ABSTRACT

A vertically-stacked three-dimensional nanocrystal memory device and a method for manufacturing the same is proposed. Each of the two vertically overlapping memory cells of the vertically-stacked three-dimensional nanocrystal memory device includes a thin-film transistor and nanocrystals embedded in a gate dielectric layer of the thin-film transistor. With the two vertically overlapping memory cells including, sharing and being controlled by a wordline, the bit density of the memory increases.

### FIELD OF THE INVENTION

The present invention is related to semiconductor devices and methods for manufacturing the same, and more particularly, to a thin-film transistor (TFT) nanocrystal memory device and a method for manufacturing the same.

### BACKGROUND OF THE INVENTION

Owing to the wide use of electronic products and computer related products, there is increasingly great demand for semiconductor memory devices. Hence, one of the key topics for recent research and development of semiconductor memory process is about fabricating a three-dimensional memory by disposing and stacking layers of memory cells on a substrate. The substrate of a three-dimensional memory is provided with layers of memory devices such that the memory devices are not necessarily formed on the substrate and disposed in a single layer but stacked on top of each other. Nevertheless, it is rather intricate and difficult to perform a three-dimensional memory process.

A problem in stacking memory devices in three dimensions according to the prior art is that not every memory device can be a good three-dimensional memory device. Taking passive memory devices as an example, they can be stacked up after being connected to transistors on a substrate by interconnects for selection and switching. However, stacked in this way, every layer of memory devices incurs a mask cost and necessitates complicated subsequent process adjustment to the detriment of the fabrication of a vertically-stacked three-dimensional memory. In the past, memory cell layers were stacked in an array so as to allow a mask to be shared by all the memory cell layers within the memory cell array without dealing with the mask of each memory cell layer within the memory cell array and performing subsequent process adjustment, but the problems of performing mask design required for the interconnects between every memory cell layer and the substrate within the memory cell array as well as subsequent process adjustment remain unsolved.

On the other hand, the process temperature of memory devices poses another problem. Fabrication of a memory cell layer entails heating up memory devices in the memory cell layer at high temperature, and as a result the memory devices are subjected to a thermal budget. To stack a new memory cell layer on top of an existing one, memory devices in both the new memory cell layer and the lowest memory cell layer are subjected to the process temperature. In consequence memory devices in the lowest memory cell layer and that in the new memory cell layer are subjected to the thermal budget to different extents. Stacked upward in this way, memory cell layers inevitably end up in a situation where two memory cell layers always differ from each other in terms of characteristics, as a thermal budget varies from one memory cell layer to another. For the aforesaid reasons, a passive memory device is unfit for the fabrication of a vertically-stacked three-dimensional memory.

In view of the above-mentioned, at the 2003 Symposium on VLSI Technology A. J. Walker et al. proposed using a structure of Thin-film Transistor Silicon-Oxide-Nitride-Oxide-Silicon (TFT-SONOS) as a memory device of a three-dimensional memory, in an attempt to use thin-film transistors to overcome the aforesaid drawback of the prior art, that is, during the process for fabricating a flash memory according to the prior art, disposing transistors on a silicon substrate leads to high process temperature. FIG. 1 shows both a source 11 and a drain 12 made of in-situ phosphorus-doped n-type polysilicon and configured to allow phosphorus diffusion into a channel 20 made of phosphorus-doped p-type polysilicon, an oxide layer 13 formed between the source 11 and the drain 12, an oxide-nitride-oxide (ONO) layer 21 formed by oxide tunnel dielectric, nitric oxide and blocking oxide, and a gate 22 made of in-situ phosphorus-doped p-type polysilicon. Unlike its predecessor—a floating gate made of polysilicon and configured to store electric charges, the ONO layer 21 has electric charges stored in discrete traps of the nitric oxide. As for the memory device designed by A. J. Walker in accordance with the known structures and features of a SONOS (silicon oxide nitric oxide silicon) and a thin-film transistor, the process temperature of memory devices can be reduced because of the relatively low process temperature of the polysilicon in the thin-film transistor, and thus memory functions are not subject to subsequent process temperature in the course of memory devices stacking, when compared with the prior art.

Although low process temperature can be achieved by means of a thin-film transistor, a relatively high deposition temperature is required for a centrally-located ONO dielectric layer of a memory with a SONOS structure, and in consequence during a three-dimensional stacking operation the accumulated thermal budget harms the underlying transistors and hinders the process to a certain extent; and further, each memory cell layer of a three-dimensional memory fabricated in the aforesaid manner has a low bit density.

Accordingly, the most urgent issue facing the industry now is devising a memory device fit for fabrication of a stacked three-dimensional memory.

### SUMMARY OF THE INVENTION

In order to solve the aforesaid problems of the prior art, a primary objective of the present invention is to provide a three-dimensional memory device and methods of manufacturing and operating the same with a view to decreasing the process temperature of memory devices, such that, in the course of the vertically stacking of layers of memory devices to form a three-dimensional memory, the characteristics of the memory devices do not vary from layer to layer, even though the memory device layers are subjected to a thermal budget to different extents.

Another objective of the present invention is to provide an active memory device for stacking memory devices vertically to fabricate a three-dimensional memory, such that memory devices of different layers can extend outward to reach transistors disposed on a substrate even though no additional interconnect is provided in the course of the stacking of the memory device layers.

Yet another objective of the present invention is to further increase the bit density of a three-dimensional memory and make the three-dimensional memory process simpler.

To achieve the above and other objectives, the present invention provides a method for manufacturing a three-dimensional thin-film transistor (TFT) nanocrystal memory device. The method includes: (a) growing a first doped polysilicon layer on a substrate; (b) patterning the first doped polysilicon layer to form a first bitline and a second bitline, then depositing an oxide layer between the first bitline and the second bitline; (c) forming on the first bitline, the second bitline, and the oxide layer a second doped polysilicon layer having reversed polarity when compared with the polarity of the first doped polysilicon layer, such that the second doped polysilicon layer functions as a channel of the memory device; (d) forming an oxide tunnel dielectric layer on the second doped polysilicon layer; (e) forming a nanocrystal layer on the oxide tunnel dielectric layer; (f) forming a control dielectric layer on the nanocrystal layer; (g) forming a wordline layer on the control dielectric layer; (h) forming another control dielectric layer, another nanocrystal layer, another oxide tunnel dielectric layer, another second doped polysilicon layer for functioning as another channel of the memory device, and another first doped polysilicon layer, using the aforesaid steps, though in reverse order, that is, from Steps (f) to (c); (i) patterning the another first doped polysilicon layer to form a third bitline and a fourth bitline; and (j) depositing another oxide layer between the third bitline and the fourth bitline.

To achieve the above and other objectives, the present invention provides a three-dimensional thin-film transistor (TFT) nanocrystal memory device, which includes a first thin-film transistor formed on a substrate; a nanocrystal layer within a gate dielectric layer of the first thin-film transistor; and a second thin-film transistor formed on the first thin-film transistor; wherein the first thin-film transistor and the second thin-film transistor share a common wordline.

### BRIEF DESCRIPTION OF THE DRAWINGS

The present invention can be more fully comprehended by reading the detailed description of the preferred embodiments enumerated below, with reference made to the accompanying drawings, wherein:

FIG. 1 (PRIOR ART) is a schematic view showing the structure of a traditional TFT-SONOS;

FIGS. 2A to 2G illustrate a method for manufacturing a vertically-stacked three-dimensional thin-film transistor (TFT) nanocrystal memory device according to the present invention;

FIG. 3A is a schematic view showing how to write a nanocrystal group 302a″;

FIG. 3B is a schematic view showing how to write a nanocrystal group 502a′;

FIG. 4A is a schematic view showing how to read a nanocrystal group 502a′;

FIG. 4B is a schematic view showing how to read a nanocrystal group 302a″; and

FIG. 5 is a schematic view showing how to erase all nanocrystals shown in the drawing.

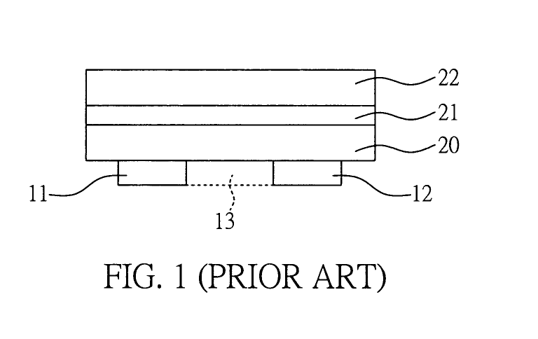

### DETAILED DESCRIPTION OF THE PREFERRED EMBODIMENTS

A vertically-stacked three-dimensional thin-film transistor (TFT) nanocrystal memory device and a method for manufacturing and operating the same according to the present invention are elucidated in the following preferred embodiments and relevant drawings.

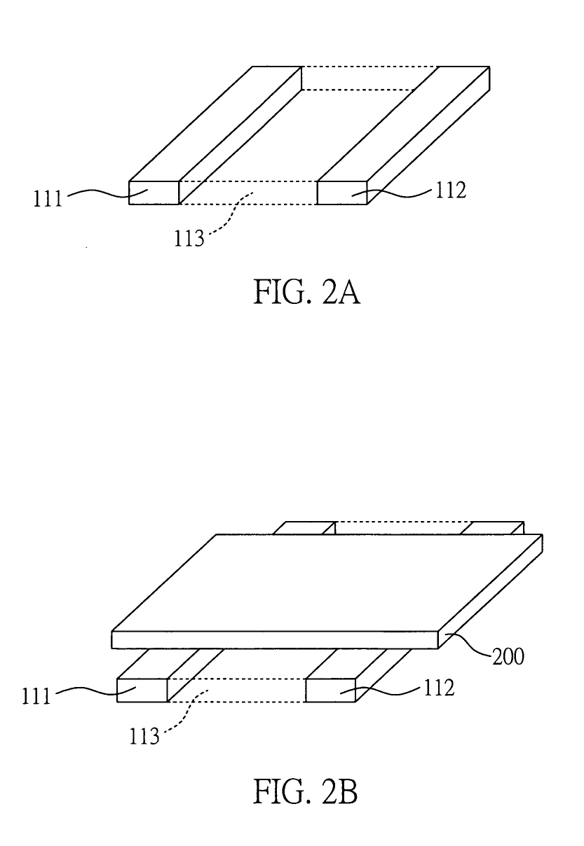

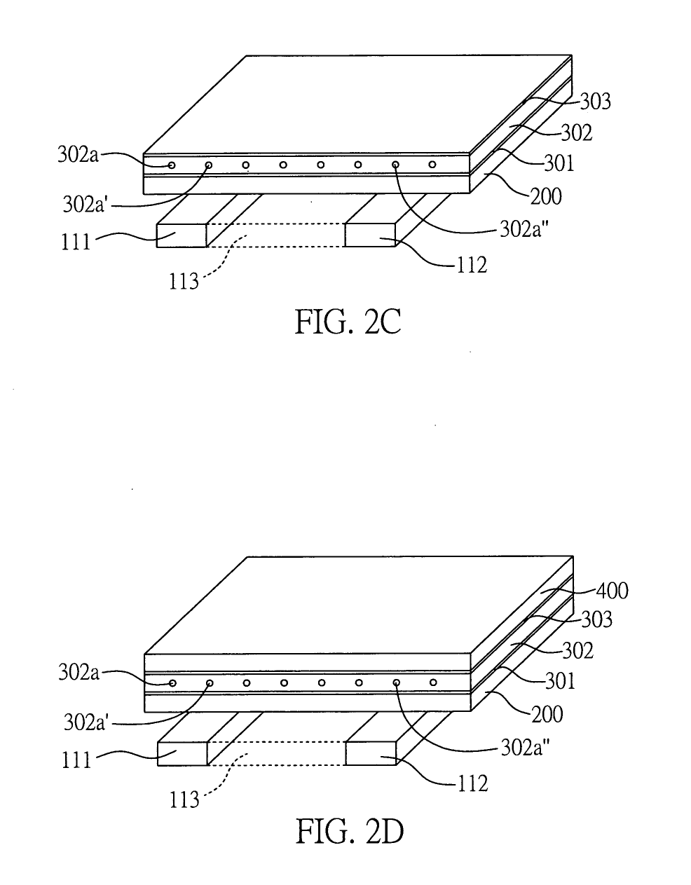

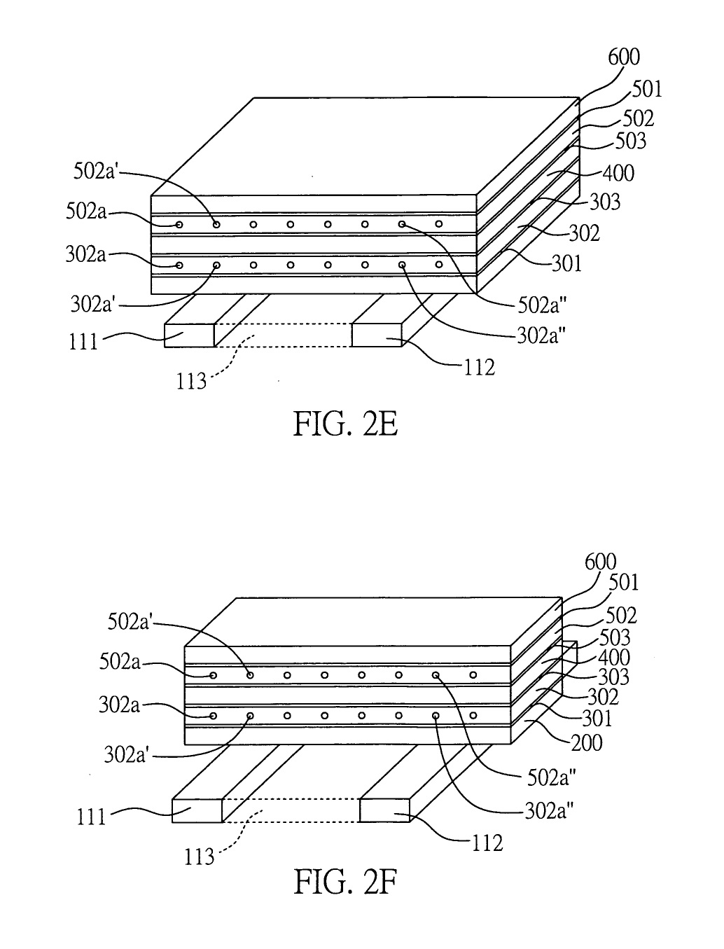

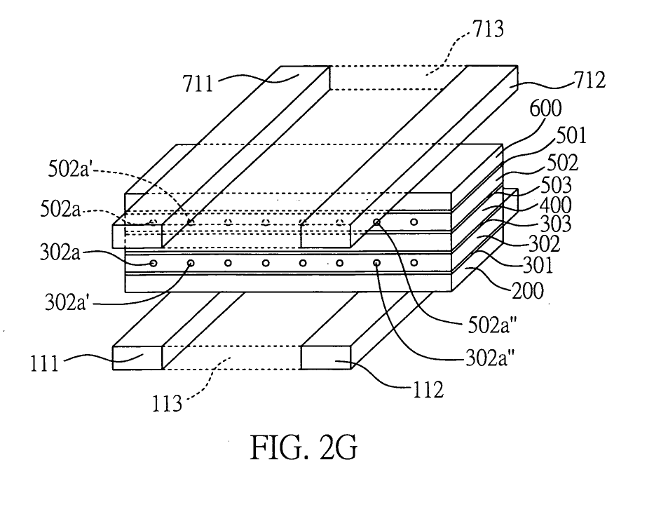

FIGS. 2A to 2G illustrate the method for manufacturing a vertically-stacked three-dimensional thin-film transistor (TFT) nanocrystal memory device according to the present invention.

FIG. 2A shows the steps of: growing a first doped polysilicon layer on a silicon substrate; patterning the first doped polysilicon layer to form a first bitline 111 and a second bitline 112, using the methods of photoresist coating, exposure and etching according to the prior; forming an oxide layer 113 between the first bitline 111 and the second bitline 112; and then planarizing the oxide layer 113 by chemical mechanical polishing (CMP).

FIG. 2B shows the steps of: forming on the first bitline 111, the second bitline 112 and the oxide layer 113 a second doped polysilicon layer having reversed polarity when compared with the polarity of the first doped polysilicon layer, such that the second doped polysilicon layer functions as a channel 200 of the memory device and contributes to the formation of a first thin-film transistor comprising the channel 200, and the first and second bitlines (drain and source) 111 and 112.

FIG. 2C shows the steps of: depositing an oxide tunnel dielectric layer 301 on the second doped polysilicon layer; forming a nanocrystal layer 302 on the oxide tunnel dielectric layer 301; and forming a control dielectric layer 303 on the nanocrystal layer 302; wherein nanocrystals 302a formed in the nanocrystal layer 302 are conventional silicon nanocrystals, germanium nanocrystals, or metallic nanocrystals of low process temperature like nickel nanocrystals, and are selectively referred to as two nanocrystal groups 302a′ and 302a″.

FIG. 2D shows the steps of: depositing a wordline layer (a gate layer) 400 on the control dielectric layer 303, wherein the wordline layer (the gate layer) 400 is made of a conventional material, such as doped polysilicon, tungsten and tantalum.

FIG. 2E shows the steps of: depositing a control dielectric layer 503 on the wordline layer (the gate layer) 400; forming a nanocrystal layer 502 on the control dielectric layer 503; and depositing an oxide tunnel dielectric layer 501 on the nanocrystal layer 502; wherein nanocrystals 502a formed in the nanocrystal layer 502 are conventional silicon nanocrystals, germanium nanocrystals, or metallic nanocrystals of low process temperature like nickel nanocrystals, and are selectively referred to as two nanocrystal groups 502a′ and 502a″; and depositing another second doped polysilicon layer on the oxide tunnel dielectric layer 501 such that the another second doped polysilicon layer functions as another channel 600 of the memory device.

FIG. 2F shows the steps of: defining a wordline layout, using the methods for applying a mask, etching and removing photoresist according to the prior art; depositing an oxide layer between the wordlines (the drawing shows a single memory device instead of all the memory cells within the memory cell array, and thus the drawing does not show any oxide layer deposited between the wordline shown and the other wordlines not shown); and then planarizing the oxide layer by chemical mechanical polishing (CMP).

Lastly, FIG. 2G shows the steps of: depositing another first doped polysilicon layer on the another second doped polysilicon layer (the another channel 600); patterning the another first doped polysilicon layer to form a third bitline 711 and a fourth bitline 712, thus contributing to the formation of a second thin-film transistor comprising the channel 600, and the third and fourth bitlines (drain and source) 711 and 712; and depositing an oxide layer 713 between the third and fourth bitlines 711 and 712. At this point, the memory device process of the present invention ends.

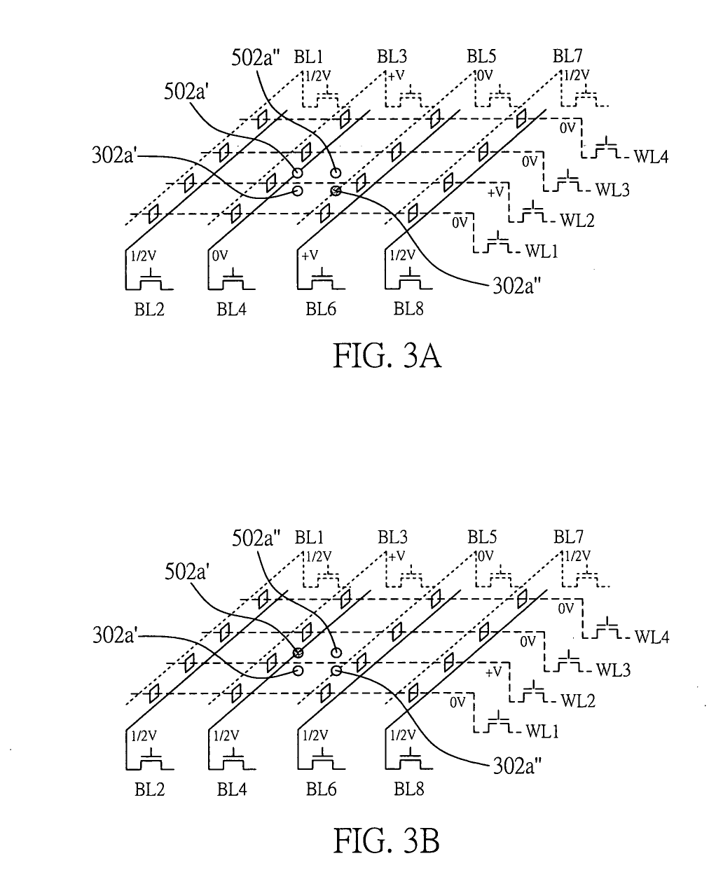

FIGS. 3 to 5 illustrate the method for operating a vertically-stacked three-dimensional thin-film transistor (TFT) nanocrystal memory according to the present invention.

Denotations used in FIGS. 3 to 5 are defined as follows. Upper bitlines of FIG. 2G are otherwise denoted by BL1, BL3, BL5 and BL7 respectively in FIGS. 3 to 5. The third bitline 711 and the fourth bitline 712 of FIG. 2G are otherwise denoted by BL3 and BL5 respectively in FIGS. 3 to 5. Bitlines adjacent to the third and fourth bitlines 711 and 712 of FIG. 2G are otherwise denoted by BL1 and BL7 respectively in FIGS. 3 to 5. Lower bitlines of FIG. 2G are otherwise denoted by BL2, BL4, BL6 and BL8 respectively in FIGS. 3 to 5. The first bitline 111 and the second bitline 112 of FIG. 2G are otherwise denoted by BL4 and BL6 respectively in FIGS. 3 to 5. Bitlines adjacent to the first and second bitlines 111 and 112 of FIG. 2G are otherwise denoted by BL2 and BL8 respectively in FIGS. 3 to 5. Wordlines disposed within the memory cell array composed of the memory devices of the present invention are denoted by WL1, WL2, WL3 and WL4 respectively in FIGS. 3 to 5. The wordline layer 400 of FIG. 2G is otherwise denoted by WL2 in FIGS. 3 to 5. Two electrically distinguishable nanocrystal groups disposed in the nanocrystal layer 502 of FIG. 2G are denoted by 502a′ and 502a″ respectively in FIGS. 3 to 5. Two electrically distinguishable nanocrystal groups disposed in the nanocrystal layer 302 of FIG. 2G are denoted by 302a′ and 302a″ respectively in FIGS. 3 to 5.

As shown in FIG. 3A, the nanocrystal group 302a″ is written, by applying voltage of one unit to the wordline WL2, voltage of half a unit (background voltage) to the bitlines BL1, BL3, BL5, BL7, BL2, and BL8 respectively, voltage of one unit to the bitline BL6, and no voltage to the bitline BL4. As shown in FIG. 3B, the nanocrystal group 502a′ is written, by applying voltage of one unit to the wordline WL2, voltage of half a unit (background voltage) to the bitlines BL2, BL4, BL6, BL8, BL1, and BL7 respectively, voltage of one unit to the bitline BL3, and no voltage to the bitline BL5. In this embodiment, as shown in the drawings, the applied voltages are meaningful because of a voltage difference rather than a specific voltage level, and thus the applied voltages may be adjusted if necessary. Any intended nanocrystal may be written, using the aforesaid operating method.

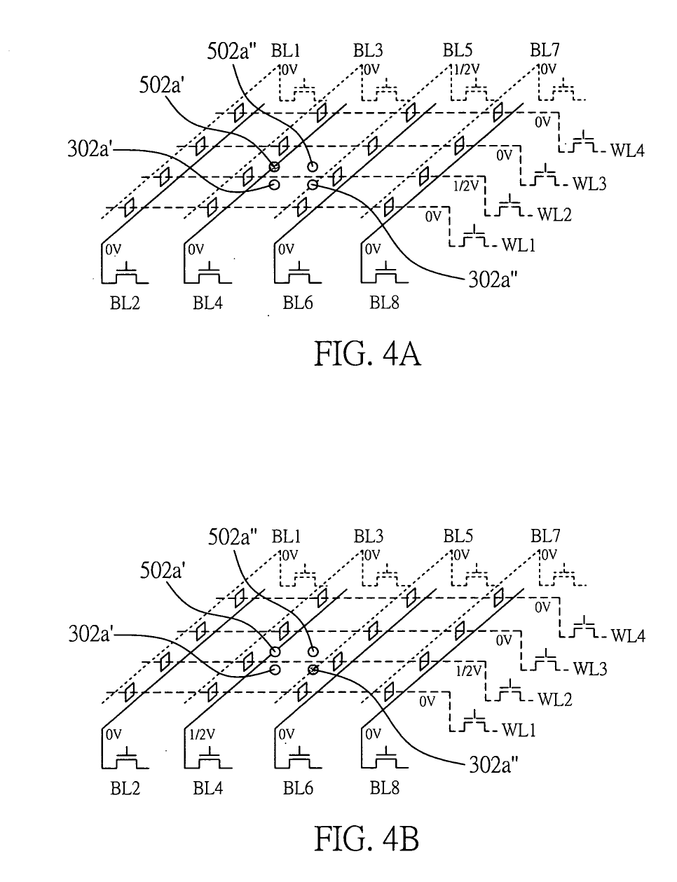

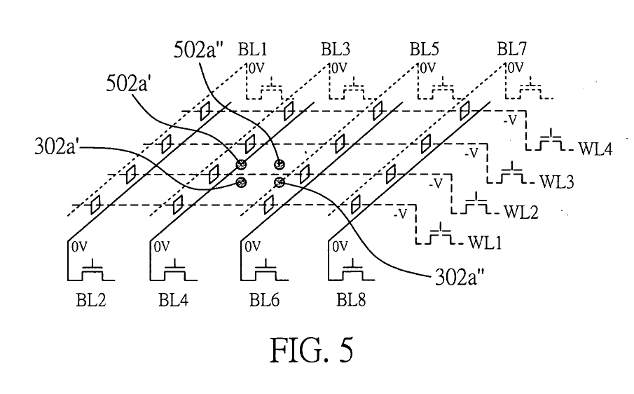

As shown in FIG. 4A, taking reverse read as an example, the nanocrystal group 502a′ is read, by applying voltage of half a unit to the wordline WL2, voltage of half a unit to the bitline BL5, and no voltage to the other bitlines. As shown in FIG. 4B, the nanocrystal group 302a″ is read, by applying voltage of half a unit to the wordline WL2, voltage of half a unit to the bitline BL4, and no voltage to the other bitlines. When compared with FIGS. 3A and 3B, FIGS. 4A and 4B show that relatively low voltage is applied to the wordline WL2; it is because FIGS. 4A and 4B illustrate a situation where a nanocrystal is read instead of written and therefore no high applied voltage is required, and, in other words, the situation illustrated by FIGS. 4A and 4B requires applying relatively low voltage to the wordline WL2 so as to open the channel concerned but avoid ushering electric charges into any nanocrystal. As described above, the applied voltages are meaningful because of a voltage difference rather than a specific voltage level, and thus the applied voltages may be adjusted if necessary. Any intended nanocrystal may be read, using the aforesaid operating method.

Referring to FIG. 5, all the nanocrystals shown in the drawing are erased, by grounding all the bitlines and applying negative bias voltage to all the wordlines.

The preferred embodiments described above only serve the purpose of explaining the principle and effects of the present invention, and are not to be used to limit the scope of the present invention. Basing on the purpose and the scope of the present invention, the present invention encompasses various modifications and similar arrangements, and its scope should be covered by the claims listed in the following pages.

What is claimed is:

1. A method for manufacturing a three-dimensional thin-film transistor (TFT) nanocrystal memory device, the method comprising:
(a) growing a first doped polysilicon layer on a substrate;
(b) patterning the first doped polysilicon layer to form a first bitline and a second bitline, then depositing an oxide layer between the first bitline and the second bitline;
(c) forming on the first bitline, the second bitline, and the oxide layer a second doped polysilicon layer having reversed polarity when compared with the polarity of the first doped polysilicon layer, such that the second doped polysilicon layer functions as a channel of the memory device;
(d) forming an oxide tunnel dielectric layer on the second doped polysilicon layer;
(e) forming a nanocrystal layer on the oxide tunnel dielectric layer;
(f) forming a control dielectric layer on the nanocrystal layer;
(g) forming a wordline layer on the control dielectric layer;
(h) forming another control dielectric layer, another nanocrystal layer, another oxide tunnel dielectric layer, another second doped polysilicon layer for functioning as another channel of the memory device, and another first doped polysilicon layer, using the aforesaid steps, though in reverse order, that is, from Steps (f) to (c);
(i) patterning the another first doped polysilicon layer to form a third bitline and a fourth bitline; and
(j) depositing another oxide layer between the third bitline and the fourth bitline.

2. The method for manufacturing a three-dimensional thin-film transistor (TFT) nanocrystal memory device of claim 1 further comprising planarizing both the oxide layer deposited between the first and second bitlines and the another oxide layer deposited between the third and fourth bitlines by chemical mechanical polishing (CMP).

3. The method for manufacturing a three-dimensional thin-film transistor (TFT) nanocrystal memory device of claim 1 further comprising forming a first thin-film transistor by the first and second bitlines formed by the first doped polysilicon layer, the second doped polysilicon layer formed on the first and second bitlines, and the wordline layer, forming a second thin-film transistor by the wordline layer, the second doped polysilicon layer formed on the wordline layer, and the third and fourth bitlines formed on the first doped polysilicon layer.

4. The method for manufacturing a three-dimensional thin-film transistor (TFT) nanocrystal memory device of claim 1, wherein the nanocrystal layers comprise silicon nanocyrstals.

5. The method for manufacturing a three-dimensional thin-film transistor (TFT) nanocrystal memory device of claim 1, wherein the nanocrystal layers comprise germanium nanocyrstals.

6. The method for manufacturing a three-dimensional thin-film transistor (TFT) nanocrystal memory device of claim 1, wherein the nanocrystal layers comprise metallic nanocrystals of low process temperature.

7. The method for manufacturing a three-dimensional thin-film transistor (TFT) nanocrystal memory device of claim 6, wherein the metallic nanocrystals of low process temperature is nickel nanocrystals.

8. A three-dimensional thin-film transistor (TFT) nanocrystal memory device comprising:
a first thin-film transistor formed on a substrate;
a nanocrystal layer within a gate dielectric layer of the first thin-film transistor; and
a second thin-film transistor formed on the first thin-film transistor;
wherein the first thin-film transistor and the second thin-film transistor share a common wordline.

9. The three-dimensional thin-film transistor (TFT) nanocrystal memory device of claim 8, wherein either of the first and second thin-film transistors and nanocrystals embedded in the nanocrystal layer thereof together form a memory cell.

10. The three-dimensional thin-film transistor (TFT) nanocrystal memory device of claim 9 comprising two memory cells which share the wordline and thereby vertically overlap each other.

11. The three-dimensional thin-film transistor (TFT) nanocrystal memory device of claim 10, wherein both of the vertically overlapping memory cells are penetrated and controlled by the wordline.

12. A three-dimensional thin-film transistor (TFT) nanocrystal memory comprising:
a memory cell array which comprises a plurality of three-dimensional thin-film transistor (TFT) nanocrystal memory devices of claim 8; and
selection transistors for connection with bitlines and wordlines of the memory cell array.

13. The three-dimensional thin-film transistor (TFT) nanocrystal memory of claim 12, wherein the memory devices to be written, read and erased are selected by the bitline-related selection transistors and the wordline-related selection transistors of the memory cell array.

14. The three-dimensional thin-film transistor (TFT) nanocrystal memory of claim 13, wherein the writing, reading and erasure of the memory devices are controlled by voltages applied to the wordlines and the bitlines in the thin-film transistors of the memory devices.
